(19) United States
(12) Patent Application Publication
(10) Pub. No.: US 2025/0381886 A1
(43) Pub. Date: Dec. 18, 2025

(54) APPARATUS FOR CONTROLLING TEMPERATURE RISE OF VEHICLE BATTERY AND METHOD THEREOF

(71) Applicants: HYUNDAI MOTOR COMPANY, SEOUL (KR); KIA CORPORATION, SEOUL (KR); NVH KOREA, INC., Hwaseong-si (KR)

(72) Inventors: Yo Han BAEK, Hwaseong-si (KR); Hyo Kyung LEE, Hwaseong-si (KR); Yoon Sung CHOI, Hwaseong-si (KR)

(21) Appl. No.: 18/935,337

(22) Filed: Nov. 1, 2024

(30) Foreign Application Priority Data
Jun. 17, 2024 (KR) 10-2024-0078315

(51) Int. Cl. B60L 58/27; B60L 58/12; G01K 3/00; G01R 31/374; G01R 31/382; H01M 10/48; H01M 10/615; H01M 10/625; H01M 10/633; H01M 10/637; H01M 10/66

(52) U.S. Cl. CPC B60L 58/27; B60L 58/12; G01K 3/005; G01R 31/374; G01R 31/382; H01M 10/486; H01M 10/615; H01M 10/625; H01M 10/633; H01M 10/637; H01M 10/66; B60L 2240/545; H01M 2220/20

(57) ABSTRACT

Disclosed are an apparatus and associated method for controlling a temperature rise of a vehicle battery. The apparatus determines whether to increase the temperature of the battery provided in the vehicle, determines the maximum power to be supplied to a motor based on a battery power map, supplies the maximum power to the motor while the motor is separated from a drive axle, and transfers heat from motor coolant whose temperature has risen to battery coolant, thereby efficiently increasing the temperature of the battery without providing a separate heater.

### CROSS-REFERENCE TO RELATED APPLICATION

This application claims the benefit of priority to Korean Patent Application No. 10-2024-0078315, filed in the Korean Intellectual Property Office on Jun. 17, 2024, the entire contents of which are incorporated herein by reference.

### TECHNICAL FIELD

The present disclosure relates to a technology for controlling the temperature rise of a battery (e.g., a high-voltage battery) provided in a vehicle (e.g., an electric vehicle and a hybrid electric vehicle).

### BACKGROUND

In general, lithium polymer batteries (LiPB), which provide power in electric vehicles, are secondary batteries that use a solid electrolyte with excellent ionic conductivity, and have low risk of electrolyte leakage, explosion, and internal resistance. In addition, lithium polymer batteries have high energy density and have no memory effect, so their lifespan does not decrease even when they are not fully charged or fully discharged.

When such a lithium polymer battery is charged at a low temperature, the overvoltage rise between the anode and the cathode increases asymmetrically, reducing the charging capacity compared to charging at room temperature, and the cathode voltage drops to a very low voltage, causing metallic lithium to precipitate (educe). When this is repeated over a long period of time, there is a risk of performance deterioration and internal short circuit of the lithium polymer battery.

Therefore, in order to use the lithium polymer battery efficiently, ensure safety of the lithium polymer battery, and secure the durable life of the lithium polymer battery, it is required to manage the temperature of the lithium polymer battery.

Meanwhile, as a related art to increase the temperature of a battery (e.g., a lithium polymer battery) provided in a vehicle, a heater-based temperature rise technology and a temperature rise technology using heat generation from an inverter switch have been proposed.

The heater-based temperature rise technology is a technology that converts the electric energy of a battery into heat energy using a heater and uses the heat energy to increase the temperature of the battery. Because the heater excessively consumes energy of the battery, not only does the efficiency of the battery decrease, but the fuel efficiency of the vehicle also decreases.

The temperature rise technology using the heat generated by the switch of an inverter takes a lot of time to raise the temperature of a battery to an appropriate temperature because the amount of heat generated from the switch is low, and it is difficult to properly demonstrate the temperature rise performance, especially during cold waves in winter.

The matters described in this background section are intended to promote an understanding of the background of the disclosure and may include matters that are not already known to those of ordinary skill in the art.

### SUMMARY

The present disclosure has been made to solve the above-mentioned problems occurring in the prior art while advantages achieved by the prior art are maintained intact.

One aspect of the present disclosure provides an apparatus for controlling a temperature rise of a vehicle battery and a method thereof capable of efficiently increasing the temperature of the battery without providing a separate heater by determining whether to increase the temperature of the battery provided in the vehicle, determining the maximum power to be supplied to a motor based on a battery power map, supplying the maximum power to the motor while the motor is separated from the drive axle, and transferring heat from motor coolant whose temperature has risen to battery coolant.

Another aspect of the present disclosure provides an apparatus for controlling a temperature rise of a vehicle battery and a method thereof capable of efficiently increasing the temperature of the battery without providing a separate heater by determining whether to increase the temperature of the battery provided in the vehicle, determining a charging current and a discharging current of the battery based on a state of charge (SOC) of the battery, and causing heat generation in an internal resistance of the battery by alternately repeating charging and discharging of the battery at a preset cycle.

Another aspect of the present disclosure provides an apparatus for controlling a temperature rise of a vehicle battery and a method thereof capable of efficiently increasing the temperature of the battery without providing a separate heater by determining whether to increase the temperature of the battery provided in the vehicle, determining the maximum power to be supplied to the motor based on a battery power map, supplying the maximum power to the motor while the motor is separated from the drive axle, and transferring heat from motor coolant whose temperature has risen to battery coolant, determining a charging current and a discharging current of the battery based on a SOC of the battery, and causing heat generation in an internal resistance of the battery by alternately repeating charging and discharging of the battery at a preset cycle.

The technical problems to be solved by the present disclosure are not limited to the aforementioned problems, and any other technical problems not mentioned herein will be clearly understood from the following description by those skilled in the art to which the present disclosure pertains. Also, it may be easily understood that the objects and advantages of the present disclosure may be realized by the units and combinations thereof recited in the claims.

According to one aspect of the present disclosure, an apparatus for controlling a temperature rise of a battery for a vehicle, which includes a motor that uses power of the battery to rotate a drive axle, a separator that separates the motor from the drive axle, and a heat exchanger, includes a controller that determines a maximum power to be supplied to the motor, supplies the maximum power to the motor while the motor is separated from the drive axle, and controls the heat exchanger to transfer heat from motor coolant to battery coolant when a temperature of the battery is increased.

According to an embodiment, the apparatus may further include storage that stores a battery power map in which a discharge power and a charge power corresponding to a state of charge (SOC) and the temperature of the battery are recorded.

According to an embodiment, the controller may determine the maximum power to be supplied to the motor based on the battery power map.

According to an embodiment, the apparatus may further include a temperature sensor that measures the temperature of the battery.

According to an embodiment, the controller may determine to increase the temperature of the battery when the temperature of the battery does not exceed a threshold temperature.

According to an embodiment, the controller may terminate the temperature rise of the battery when the temperature of the battery reaches a target temperature.

According to an embodiment, the controller may separate the motor from the drive axle in conjunction with a disconnector actuator system (DAS).

According to an embodiment, the controller may transfer heat from the motor coolant whose temperature has risen to the battery coolant in conjunction with the heat exchanger.

According to an embodiment, the controller may determine a charging current and a discharging current of the battery based on a state of charge (SOC) of the battery, and cause heat generation due to an internal resistance of the battery by alternately repeating charging and discharging of the battery at a preset cycle.

According to an embodiment, the controller may terminate the heat generation in the internal resistance of the battery when the temperature of the battery reaches a target temperature.

According to another aspect of the present disclosure, a method of controlling a temperature rise of a battery for a vehicle, which includes a motor that uses power of the battery to rotates a drive axle, a separator that separates the motor from the drive axle, and a heat exchanger, includes, when a temperature of the battery is increased, determining, by a controller, a maximum power to be supplied to the motor, supplying, by the controller, the maximum power to the motor while the motor is separated from the drive axle, and controlling, by the controller, the heat exchanger to transfer heat from motor coolant to battery coolant.

According to an embodiment, the method may further include storing, by storage, a battery power map in which a discharge power and a charge power corresponding to a state of charge (SOC) and the temperature of the battery are recorded.

According to an embodiment, the determining of the maximum power may include determining the maximum power to be supplied to the motor based on the battery power map.

According to an embodiment, the method may further include measuring, by a temperature sensor, the temperature of the battery, determining to increase the temperature of the battery when the temperature of the battery does not exceed a threshold temperature, and terminating the temperature rise of the battery when the temperature of the battery reaches a target temperature.

According to an embodiment, the supplying of the maximum power to the motor may include separating the motor from the drive axle in conjunction with a disconnector actuator system (DAS).

According to an embodiment, the controlling of the heat exchanger to transfer the heat may include transferring the heat from the motor coolant whose temperature has risen to the battery coolant in conjunction with the heat exchanger.

According to an embodiment, the method may further include determining, by the controller, a charging current and a discharging current of the battery based on a state of charge (SOC) of the battery, causing, by the controller, heat generation due to an internal resistance of the battery by alternately repeating charging and discharging of the battery at a preset cycle, and terminating, by the controller, the heat generation in the internal resistance of the battery when the temperature of the battery reaches a target temperature.

### BRIEF DESCRIPTION OF THE DRAWINGS

The above and other objects, features and advantages of the present disclosure will be more apparent from the following detailed description taken in conjunction with the accompanying drawings:

FIG. 1 is a diagram illustrating a configuration of an apparatus for controlling a temperature rise of a vehicle battery according to an embodiment of the present disclosure;

FIG. 2 is a diagram illustrating an example of an operation of increasing the temperature of a battery by a controller provided in an apparatus for controlling a temperature rise of a vehicle battery according to an embodiment of the present disclosure;

FIG. 3 is a diagram illustrating heat generated by a motor used in an embodiment of the present disclosure;

FIG. 4 is a flowchart of a method of controlling a temperature rise of a vehicle battery according to an embodiment of the present disclosure; and

FIG. 5 is a block diagram illustrating a computing system for executing a method of controlling a temperature rise of a vehicle battery according to each embodiment of the present disclosure.

### DETAILED DESCRIPTION

Hereinafter, some embodiments of the present disclosure will be described in detail with reference to the exemplary drawings. In adding the reference numerals to the components of each drawing, it should be noted that the identical or equivalent component is specified by the identical numeral even when they are displayed on other drawings. Further, in describing the embodiment of the present disclosure, a detailed description of the related known configuration or function will be omitted when it is determined that it interferes with the understanding of the embodiment of the present disclosure.

In addition, terms, such as first, second, A, B, (a), (b) or the like may be used herein when describing components of the present disclosure. The terms are provided only to distinguish the elements from other elements, and the essences, sequences, orders, and numbers of the elements are not limited by the terms. In addition, unless defined otherwise, all terms used herein, including technical or scientific terms, have the same meanings as those generally understood by those skilled in the art to which the present disclosure pertains. The terms defined in the generally used dictionaries should be construed as having the meanings that coincide with the meanings of the contexts of the related technologies, and should not be construed as ideal or excessively formal meanings unless clearly defined in the specification of the present disclosure.

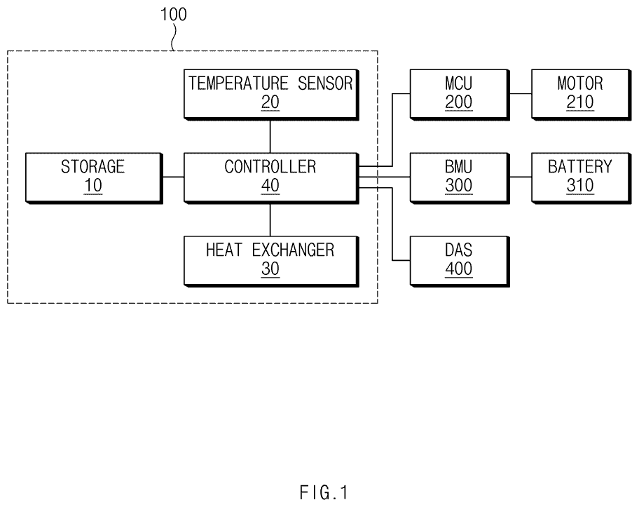

FIG. 1 is a diagram illustrating a configuration of an apparatus for controlling a temperature rise of a vehicle battery according to an embodiment of the present disclosure.

As shown in FIG. 1, an apparatus 100 for controlling a temperature rise of a vehicle battery according to an embodiment of the present disclosure may include storage 10, a temperature sensor 20, a heat exchanger 30, and a controller 40. In this embodiment, depending on a scheme of implementing the apparatus 100 for controlling a temperature rise of a vehicle battery, components may be combined with each other to be implemented as one, or some components may be omitted.

Regarding each component, first, the storage 10 may store a battery power map in which discharge power and charge power corresponding to the SOC and temperature of a battery 310 are recorded. In this case, the battery power map may be received from a battery management unit (BMU) 300. In addition, the battery may include a high-voltage battery that supplies power to an electric vehicle or a hybrid electric vehicle. In this case, the BMU 300, which is a device or a system that manages and monitors the battery 310, may manage the charging and discharging of the battery 310 to maintain optimal performance, and monitor the voltage, current, temperature, capacity, and the like of the battery 310, thereby preventing the battery 310 from being over-charged and over-discharged. In addition, the BMU 300 may perform voltage balancing between cells of the battery.

The storage 10 may store various logic, algorithms, and programs required in the process of determining whether to increase the temperature of the battery 310 provided in a vehicle, determining the maximum power to be supplied to a motor 210 based on the battery power map, supplying the maximum power to the motor 210 while the motor 210 is separated from the drive axle, and transferring heat from motor coolant whose temperature has risen to battery coolant.

The storage 10 may store various logic, algorithms, and programs required in the process of determining whether to increase the temperature of the battery 310 provided in a vehicle, determining a charging current and a discharging current of the battery 310 based on a state of charge (SOC) of the battery 310, and causing heat generation in an internal resistance of the battery 310 by alternately repeating charging and discharging of the battery 310 at a preset cycle.

The storage 10 may store various logic, algorithms, and programs required to perform a first process of determining whether to increase the temperature of the battery 310 provided in a vehicle, determining the maximum power to be supplied to the motor 210 based on the battery power map, supplying the maximum power to the motor 210 while the motor 210 is separated from the drive axle, and transferring heat from motor coolant whose temperature has risen to battery coolant, and a second process of determining a charging current and a discharging current of the battery 310 based on a SOC of the battery 310, and causing heat generation in an internal resistance of the battery 310 by alternately repeating charging and discharging of the battery 310 at a preset cycle.

The temperature sensor 20, which is a module that measures the temperature of the battery 310, may measure, for example, the temperature of coolant (hereinafter, referred to as battery coolant) that cools the battery 310.

The heat exchanger 30 may be implemented, for example, as a condenser and may transfer heat from coolant (hereinafter, referred to as motor coolant) that cools the motor 210 to the battery coolant.

The controller 40 may be electrically connected to each component and may perform overall control such that each component performs its function. The controller 40 may be implemented in the form of hardware or software, or may be implemented in a combination of hardware and software. Preferably, the controller 40 may be implemented as a microprocessor, but is not limited thereto.

In a first embodiment, the controller 40 may determine whether to increase the temperature of the battery 310 provided in a vehicle, determine the maximum power to be supplied to a motor 210 based on the battery power map stored in the storage 10, supply the maximum power to the motor 210 while the motor 210 is separated from the drive axle, and transfer heat from motor coolant whose temperature has risen to battery coolant.

In this embodiment, when the temperature of the battery 310 obtained through the temperature sensor 20 does not exceed a threshold temperature, the controller 40 may determine to increase the temperature of the battery 310 (i.e., it may be determined to increase the temperature of the battery 310). In this case, when the temperature of the battery 310 obtained through the temperature sensor 20 does not exceed the threshold temperature while receiving permission from the user to increase the temperature, the controller 40 may determine to increase the temperature of the battery 310 (i.e., it may be determined to increase the temperature of the battery 310). In addition, the controller 40 may store the battery power map obtained from the BMU 300 in the storage 10. In addition, in order to protect the battery 310, the controller 40 may determine the maximum power to be supplied to the motor 210 by maximizing the current and amount of current within an allowable range of the battery power map. In addition, the controller 40 may separate the motor 210 from the drive axle in conjunction with a disconnector actuator system (DAS) 400. In addition, the controller 40 may control the driving of the motor 210 in conjunction with a motor control unit (MCU) 200.

In addition, the controller 40 may terminate the temperature rise of the battery 310 when the temperature of the battery 310 reaches the target temperature.

In addition, the DAS 400 may perform a function of mechanically connecting or blocking the vehicle wheel shaft and reducer to provide the power generated through the motor and reducer of an electric-four wheel drive (e-4WD) system to the vehicle. That is, the DAS 400 may transmit power by connecting the vehicle wheel shaft and the reducer when the motor is driven, and may block the power by releasing the connection when the motor is not driven.

The DAS 400 may be mounted on the reducer side of the assembly of the e-4WD system including the motor and the reducer, and may include a vehicle wheel shaft, a hub, an actuator, a shift fork, a spring, and a sleeve.

The DAS 400 may compress or expand the spring by operating the actuator, and may fasten (transmit power) or release (block power) the vehicle wheel shaft and the hub on the reducer side through the shift fork moved by elastic force. In this embodiment, in the released state, the motor and the reducer do not rotate.

In a second embodiment, the controller 40 may determine whether to increase the temperature of the battery 310 provided in a vehicle, determine a charging current and a discharging current of the battery 310 based on a SOC of the battery 310, and cause heat generation in an internal resistance of the battery 310 by alternately repeating charging and discharging of the battery 310 at a preset cycle. In this case, the heat generation in the internal resistance of the battery 310 occurs in proportion to the square of the current and the amount of current.

The controller 40 may terminate the heat generation in the internal resistance of the battery 310 when the temperature of the battery 310 reaches a target temperature. That is, the controller 40 may stop the operation of causing heat generation in the internal resistance of the battery 310.

In a third embodiment, the controller 40 may determine whether to increase the temperature of the battery 310 provided in a vehicle, determine the maximum power to be supplied to the motor 210 based on the battery power map stored in the storage 10, supply the maximum power to the motor 210 while the motor 210 is separated from the drive axle, transfer heat from motor coolant whose temperature has risen to battery coolant, determine a charging current and a discharging current of the battery 310 based on a SOC of the battery 310, and cause heat generation in an internal resistance of the battery 310 by alternately repeating charging and discharging of the battery 310 at a preset cycle.

Meanwhile, the controller 40 may determine a driving state and a stopped state of the vehicle, determine a battery load and available heating power in the driving state, and determine the battery load and the available heating power in the stopped state.

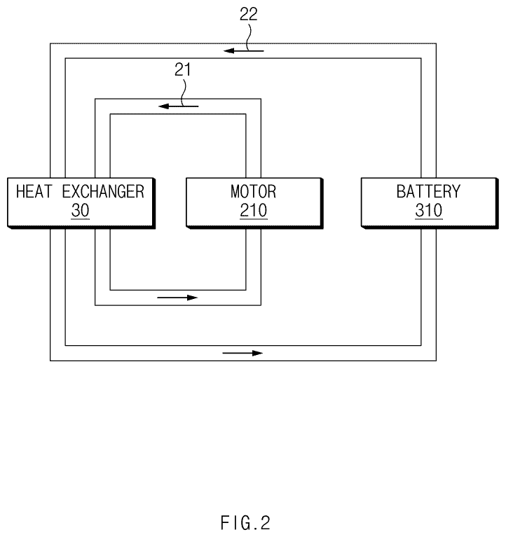

FIG. 2 is a diagram illustrating an example of an operation of increasing the temperature of a battery by a controller provided in an apparatus for controlling a temperature rise of a vehicle battery according to an embodiment of the present disclosure.

As shown in FIG. 2, the coolant that cools the motor 210 circulates through a first path 21, and the coolant that cools the battery 310 circulates through a second path 22.

The controller 40 operates the motor 210 at the maximum power in conjunction with the MCU 200 to generate heat in the motor 210, and the heat generated in such a manner increases the temperature of the motor coolant. The motor coolant whose temperature has risen in such a manner circulates through the first path 21, and the heat exchanger 30 moves the heat of the motor coolant to the battery coolant to increase the temperature of the battery coolant. As the battery coolant whose temperature rises in such a manner passes through the battery 310, the temperature of the battery 310 is increased.

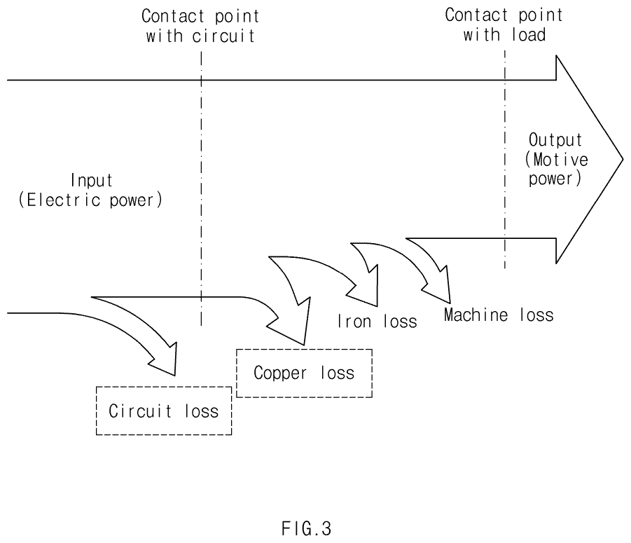

FIG. 3 is a diagram illustrating heat generated by a motor used in an embodiment of the present disclosure.

As shown in FIG. 3, electric power supplied to the motor 210 is not 100% transmitted to the motor 210 and may be converted to heat due to various causes. That is, the power transmitted to the motor 210 may be converted into heat due to, for example, circuit loss, coil loss, iron loss, machine loss, and the like.

In this case, the circuit loss refers to the loss caused when the power transmitted to the motor 210 is converted to heat while passing through various elements on the circuit, and the coil loss refers to the loss caused when the power transmitted to the motor 210 passes through a coil. In addition, the iron loss refers to the loss caused due to heat generated as a rotor rotates, and loss due to heat generated by a permanent magnet.

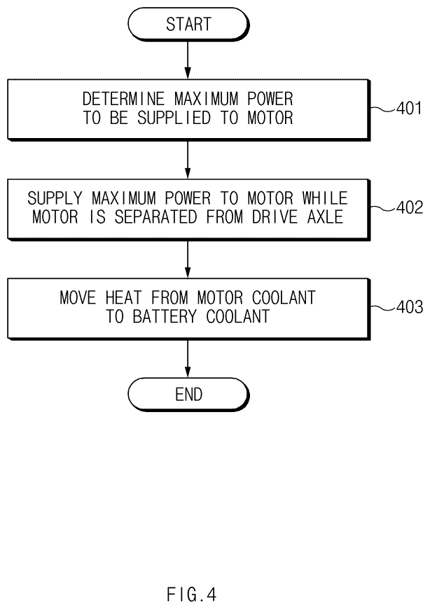

FIG. 4 is a flowchart of a method of controlling a temperature rise of a vehicle battery according to an embodiment of the present disclosure.

First, in 401, the controller 40 determines the maximum power to be supplied to the motor 210 based on the battery power map.

Next, in 402, the controller 40 supplies the maximum power to the motor 210 in a state in which the motor 210 is separated from the drive axle. In this case, the controller 40 may separate the motor 210 from the drive axle in conjunction with the DAS 400.

Next, in 403, the controller 40 moves heat from the motor coolant to the battery coolant in conjunction with the heat exchanger 30.

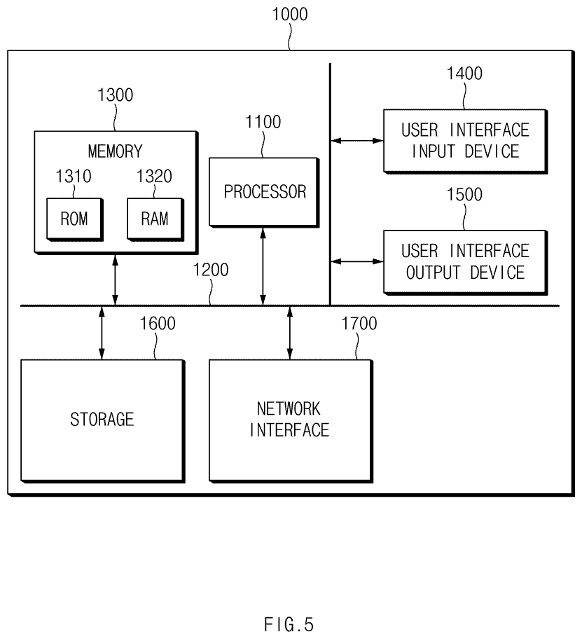

FIG. 5 is a block diagram illustrating a computing system for executing a method of controlling a temperature rise of a vehicle battery according to each embodiment of the present disclosure.

Referring to FIG. 5, as described above, the method of controlling a temperature rise of a vehicle battery according to an embodiment of the present disclosure may be implemented through a computing system 1000. The computing system 1000 may include at least one processor 1100, a memory 1300, a user interface input device 1400, a user interface output device 1500, storage 1600, and a network interface 1700 which are connected through a system bus 1200.

The processor 1100 may be a central processing unit (CPU) or a semiconductor device that processes instructions stored in the memory 1300 and/or the storage 1600. The memory 1300 and the storage 1600 may include various volatile or nonvolatile storage media. For example, the memory 1300 may include a read only memory (ROM) 1310 and a random access memory (RAM) 1320.

Accordingly, the processes of the method or the algorithm described in relation to the embodiments of the present disclosure may be implemented directly by hardware executed by the processor 1100, a software module, or a combination thereof. The software module may reside in a storage medium (that is, the memory 1300 and/or the storage 1600), such as a RAM, a flash memory, a ROM, an EPROM, an EEPROM, a register, a hard disk, a detachable disk, or a CD-ROM. The exemplary storage medium is coupled to the processor 1100, and the processor 1100 may read information from the storage medium and may write information in the storage medium. In another method, the storage medium may be integrated with the processor 1100. The processor 1100 and the storage medium may reside in an application specific integrated circuit (ASIC). The ASIC may reside in a user terminal. In another method, the processor 1100 and the storage medium may reside in the user terminal as an individual component.

According to the embodiments of the present disclosure, it is possible to efficiently increase the temperature of a battery without providing a separate heater by determining whether to increase the temperature of the battery provided in the vehicle, determining the maximum power to be supplied to a motor based on a battery power map, supplying the maximum power to the motor while the motor is separated from the drive axle, and transferring heat from motor coolant whose temperature has risen to battery coolant.

In addition, it is possible to increase the temperature of a battery more efficiently than inverter coolant, which has a low temperature rise rate by determining whether to increase the temperature of the battery provided in the vehicle, determining the maximum power to be supplied to a motor based on a battery power map, supplying the maximum power to the motor while the motor is separated from the drive axle, and transferring heat from motor coolant whose temperature has risen to battery coolant.

The above description is a simple exemplification of the technical spirit of the present disclosure, and the present disclosure may be variously corrected and modified by those skilled in the art to which the present disclosure pertains without departing from the essential features of the present disclosure. Therefore, the disclosed embodiments of the present disclosure do not limit the technical spirit of the present disclosure but are illustrative, and the scope of the technical spirit of the present disclosure is not limited by the embodiments of the present disclosure. The scope of the present disclosure should be construed by the claims, and it will be understood that all the technical spirits within the equivalent range fall within the scope of the present disclosure.

What is claimed is:

1. An apparatus for controlling a temperature rise of a battery for a vehicle which includes a motor configured to use power of the battery to rotate a drive axle, a separator configured to separate the motor from the drive axle, and a heat exchanger, the apparatus comprising:
a controller configured to determine a maximum power to be supplied to the motor, supply the maximum power to the motor while the motor is separated from the drive axle, and control the heat exchanger to transfer heat from motor coolant to battery coolant when a temperature of the battery is increased.

2. The apparatus of claim 1, further comprising:
storage configured to store a battery power map in which a discharge power and a charge power corresponding to a state of charge (SOC) and the temperature of the battery are recorded.

3. The apparatus of claim 2, wherein the controller is configured to determine the maximum power to be supplied to the motor based on the battery power map.

4. The apparatus of claim 1, further comprising:
a temperature sensor configured to measure the temperature of the battery.

5. The apparatus of claim 4, wherein the controller is configured to determine to increase the temperature of the battery when the temperature of the battery does not exceed a threshold

6. The apparatus of claim 5, wherein the controller is configured to terminate the temperature rise of the battery when the temperature of the battery reaches a target temperature.

7. The apparatus of claim 1, wherein the controller is configured to separate the motor from the drive axle in conjunction with a disconnector actuator system (DAS).

8. The apparatus of claim 1, wherein the controller is configured to transfer heat from the motor coolant whose temperature has risen to the battery coolant in conjunction with the heat exchanger.

9. The apparatus of claim 1, wherein the controller is configured to determine a charging current and a discharging current of the battery based on a state of charge (SOC) of the battery, and cause heat generation due to an internal resistance of the battery by alternately repeating charging and discharging of the battery at a preset cycle.

10. The apparatus of claim 9, wherein the controller is configured to terminate the heat generation in the internal resistance of the battery when the temperature of the battery reaches a target temperature.

11. A method of controlling a temperature rise of a battery for a vehicle which includes a motor configured to use power of the battery to rotates a drive axle, a separator configured to separate the motor from the drive axle, and a heat exchanger, the method comprising:
when a temperature of the battery is increased,
determining, by a controller, a maximum power to be supplied to the motor;
supplying, by the controller, the maximum power to the motor while the motor is separated from the drive axle; and
controlling, by the controller, the heat exchanger to transfer heat from motor coolant to battery coolant.

12. The method of claim 11, further comprising:
storing, by storage, a battery power map in which a discharge power and a charge power corresponding to a state of charge (SOC) and the temperature of the battery are recorded.

13. The method of claim 12, wherein the determining of the maximum power includes
determining the maximum power to be supplied to the motor based on the battery power map.

14. The method of claim 11, further comprising:
measuring, by a temperature sensor, the temperature of the battery;
determining, by the controller, to increase the temperature of the battery when the temperature of the battery does not exceed a threshold temperature; and
terminating, by the controller, the temperature rise of the battery when the temperature of the battery reaches a target

15. The method of claim 11, wherein the supplying of the maximum power to the motor includes separating the motor from the drive axle in conjunction with a disconnector actuator system (DAS).

16. The method of claim 11, wherein the controlling of the heat exchanger to transfer the heat includes transferring the heat from the motor coolant whose temperature has risen to the battery coolant in conjunction with the heat exchanger.

17. The method of claim 11, further comprising:
determining, by the controller, a charging current and a discharging current of the battery based on a state of charge (SOC) of the battery;
causing, by the controller, heat generation due to an internal resistance of the battery by alternately repeating charging and discharging of the battery at a preset cycle; and
terminating, by the controller, the heat generation in the internal resistance of the battery when the temperature of the battery reaches a target temperature.
